(19) United States
(12) Patent Application Publication
(10) Pub. No.: US 2023/0260747 A1
(43) Pub. Date: Aug. 17, 2023

(54) ION IMPLANTER AND ION IMPLANTATION METHOD

(71) Applicant: SUMITOMO HEAVY INDUSTRIES ION TECHNOLOGY CO., LTD., Tokyo (JP)

(72) Inventor: Tetsuya Kudo, Ehime (JP)

(21) Appl. No.: 18/108,420

(22) Filed: Feb. 10, 2023

(30) Foreign Application Priority Data
Feb. 15, 2022 (JP) 2022-021334

(51) Int. Cl. H01J 37/317; H01J 37/147; H01J 37/20; H01J 37/304

(52) U.S. Cl. CPC H01J 37/3171; H01J 37/20; H01J 37/304; H01J 37/1474; H01J 2237/2007; H01J 2237/24535

(57) ABSTRACT

Provided is an ion implanter or the like capable of shortening a replacement time of workpieces. An ion implantation method includes (a) deflecting an ion beam by at least one of an electric field and a magnetic field in an irradiation-disabled direction in which a wafer is incapable of being irradiated with the ion beam after a first wafer is irradiated with the ion beam directed in an irradiation-enabled direction in which the wafer is capable of being irradiated with the ion beam; (b) moving the first wafer from an ion implantation position, subsequently to the step (a); (e) disposing a second wafer different from the first wafer at the ion implantation position, subsequently to the step (b); and (f) returning the ion beam from the irradiation-disabled direction to the irradiation-enabled direction, subsequently to the step (e).

### RELATED APPLICATIONS

The content of Japanese Patent Application No. 2022-021334, on the basis of which priority benefits are claimed in an accompanying application data sheet, is in its entirety incorporated herein by reference.

### BACKGROUND

### Technical Field

Certain embodiments of the present invention relate to an ion implanter and an ion implantation method.

### Description of Related Art

The related art discloses an ion implanter including a beam blocking mechanism capable of blocking an ion beam before a wafer is irradiated. The beam blocking mechanism includes a pair of shutter plates driven to be opened and closed by a motor and is switchable between a closed state in which the ion beam is physically blocked and an open state in which the ion beam passes, depending on the opening width thereof. The beam blocking mechanism is brought into the closed state when the wafer is moved to an ion implantation position, switched to the open state when ions are implanted into the wafer, and is switched to the closed state again when the wafer is moved from the ion implantation position.

### SUMMARY

According to an embodiment of the present invention, there is provided an ion implanter including a beam deflection device that deflects an ion beam by at least one of an electric field and a magnetic field, and that is switchable between an irradiation-enabled state in which the ion beam is directed in an irradiation-enabled direction in which a workpiece is capable of being irradiated with the ion beam, and an irradiation-disabled state in which the ion beam is directed in an irradiation-disabled direction in which the workpiece is incapable of being irradiated with the ion beam; a holding device that holds the workpiece to be irradiated with the ion beam; a transfer device that transfers the workpiece to or from the holding device; a processor that controls the beam deflection device, the holding device, and the transfer device; and a memory in which a program is stored. On the basis of the program, the processor executes (a) switching the beam deflection device to the irradiation-disabled state after a first workpiece held on the holding device is irradiated with the ion beam; (b) releasing the holding of the first workpiece on the holding device, subsequently to the step (a); (c) transferring the first workpiece from the holding device with the transfer device, subsequently to the step (b); (d) transferring a second workpiece different from the first workpiece to the holding device with the transfer device, subsequently to the step (c); (e) holding the second workpiece on the holding device, subsequently to the step (d); and (f) switching the beam deflection device to the irradiation-enabled state, subsequently to the step (e).

According to another embodiment of the present invention, there is provided an ion implantation method. The method includes (a) deflecting an ion beam by at least one of an electric field and a magnetic field in an irradiation-disabled direction in which a workpiece is incapable of being irradiated with the ion beam after a first workpiece is irradiated with the ion beam directed in an irradiation-enabled direction in which the workpiece is capable of being irradiated with the ion beam; (b) moving the first workpiece from an ion implantation position, subsequently to the step (a); (c) disposing a second workpiece different from the first workpiece at the ion implantation position, subsequently to the step (b); and (d) returning the ion beam from the irradiation-disabled direction to the irradiation-enabled direction, subsequently to the step (c).

### BRIEF DESCRIPTION OF THE DRAWINGS

FIG. 1 is a top view showing a schematic configuration of an ion implanter.

FIG. 2 is a side view showing the schematic configuration of the ion implanter.

FIG. 3 schematically shows an ion beam deflected from an irradiation-enabled direction to an irradiation-disabled direction by an electric field.

FIG. 4 schematically shows an ion beam deflected from the irradiation-enabled direction to the irradiation-disabled direction by a magnetic field.

FIGS. 5A and 5B show a modification example of a beam blocking mechanism.

FIGS. 6A and 6B show a modification example of the beam blocking mechanism.

FIGS. 7A and 7B show a modification example of the beam blocking mechanism.

FIGS. 8A and 8B show a modification example of the beam blocking mechanism.

FIGS. 9A and 9B show a modification example of the beam blocking mechanism.

FIG. 10 is a top view showing a schematic configuration of a wafer transfer device.

FIG. 11 schematically shows a swap operation performed by an intermediate transfer mechanism.

FIG. 12 schematically shows the swap operation performed by the intermediate transfer mechanism.

FIG. 13 schematically shows the swap operation performed by the intermediate transfer mechanism.

FIG. 14 schematically shows the swap operation performed by the intermediate transfer mechanism.

FIG. 15 is a functional block diagram of the ion implanter.

FIG. 16 is a timing chart schematically showing a basic operation of the ion implanter.

FIG. 17 is a flowchart of the basic operation of the ion implanter.

FIG. 18 schematically shows an example in which a beam scanning function and a beam deflection function are realized with one beam scanning device.

### DETAILED DESCRIPTION

In the ion implanter of the related art, the beam blocking mechanism is switched between the closed state and the open state each time a wafer serving as an ion implantation target is replaced. However, for the beam blocking mechanism that is physically driven to be opened and closed by the motor, it takes substantial time to perform the operation of opening and closing the pair of shutter plates. Therefore, the wafer replacement time becomes long.

It is desirable to provide an ion implanter or the like capable of shortening a replacement time of workpieces.

In this aspect, since the irradiation-disabled state during the workpiece replacement in the steps (b) to (e) and the irradiation-enabled state when the workpiece is irradiated with the ion beam can be quickly switched therebetween by the beam deflection device that deflects the ion beam by at least one of an electric field and a magnetic field, the replacement time of the workpieces can be shortened.

In addition, optional combinations of the above components or those obtained by exchanging the expressions of the present invention with each other between methods, devices, systems, recording media, computer programs, and the like are also effective as aspects of the present invention.

Hereinafter, embodiments for carrying out the present invention will be described in detail with reference to the drawings. In the descriptions or drawings, the same or equivalent components, members, and processing are designated by the same reference numerals, and redundant descriptions will be omitted. The scales and shapes of the respective parts shown in the drawings are set for convenience in order to facilitate the descriptions, and should not be interpreted as limiting unless otherwise specified. The embodiments are merely examples and do not limit the scope of the present invention. All the features and combinations to be described in the embodiments are not necessarily essential to the invention.

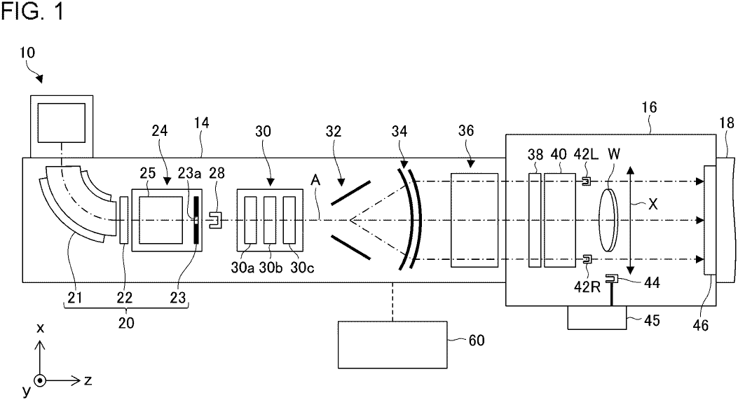

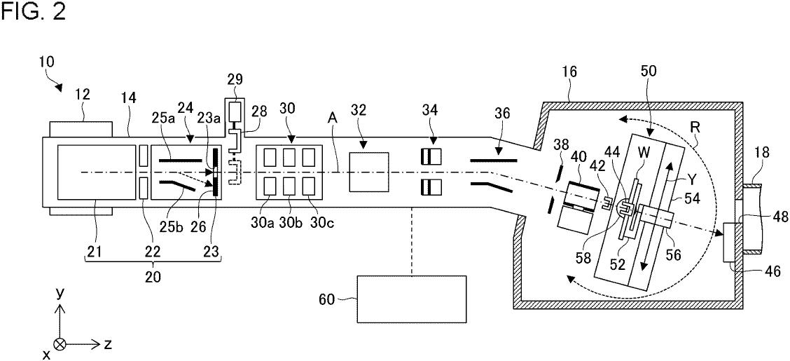

FIG. 1 is a top view showing a schematic configuration of an ion implanter 10 according to an embodiment of the present invention, and FIG. 2 is a side view showing the schematic configuration of the ion implanter 10. The ion implanter 10 is a device that performs ion implantation processing on a front surface of a workpiece W. The workpiece W is, for example, a substrate such as a semiconductor wafer or a display device. In the present specification, the workpiece W is also referred to as a wafer W for convenience, but it is not intended to limit an ion implantation processing target to a specific object or substance such as a semiconductor wafer.

The ion implanter 10 can irradiate the entire processing surface of the wafer W with an ion beam by causing an ion beam to perform reciprocating scanning in one direction (hereinafter, also referred to as a scanning direction, a beam scanning direction, or a beam movement direction) and reciprocating the wafer W in a direction (hereinafter, also referred to as a reciprocating motion direction, a reciprocating movement direction, or a wafer movement direction) perpendicular to the scanning direction. In the present specification, a traveling direction (hereinafter, also referred to as a beam traveling direction) of an ion beam which travels along a designed beamline A is defined as a z direction, and a plane perpendicular to the z direction is defined as an xy plane. In a case where the workpiece W is scanned with the ion beam, the scanning direction (beam movement direction) of the ion beam is defined as an x direction, and a y direction perpendicular to the z direction and the x direction is defined as the wafer movement direction. In this way, the reciprocating scanning with the ion beam is performed in the x direction, and the reciprocating motion of the wafer W is performed in the y direction.

The ion implanter 10 includes an ion generation device 12, a beamline unit 14, an implantation processing chamber 16, and a wafer transfer device 18. The ion generation device 12 supplies an ion beam to the beamline unit 14. The beamline unit 14 transports the ion beam supplied from the ion generation device 12 to the implantation processing chamber 16. The wafer W serving as an ion implantation target is accommodated in the implantation processing chamber 16, and ion implantation processing is performed in which the wafer W is irradiated with an ion beam supplied from the beamline unit 14. The wafer transfer device 18 serving as a transfer device transfers an unprocessed wafer before the ion implantation processing into the implantation processing chamber 16 and transfers a processed wafer after the ion implantation processing from the implantation processing chamber 16. In addition, although not shown, the ion implanter 10 is provided with an evacuating system for providing desired vacuum environments to the ion generation device 12, the beamline unit 14, the implantation processing chamber 16, and the wafer transfer device 18.

The beamline unit 14 includes a mass analyzing unit 20, a beam park device 24, a beam shaping unit 30, a beam scanning device 32, a beam parallelizing unit 34, and an angular energy filter (AEF) 36 in order from an upstream side of the beamline A. In addition, the upstream (side) of the beamline A is a side closer to the ion generation device 12, and the downstream (side) of the beamline A is a side closer to the implantation processing chamber 16 (or a beam stopper 46).

The mass analyzing unit 20 provided downstream of the ion generation device 12 selects or extracts desired ion species to be used for the ion implantation processing from the ion beam generated by the ion generation device 12 through mass analysis. The mass analyzing unit 20 includes a mass analyzing magnet 21, a mass analyzing lens 22, and a mass analyzing slit 23.

The mass analyzing magnet 21 applies a magnetic field to the ion beam extracted from the ion generation device 12 and deflects the ion beam to travel in different trajectories depending on the value of a mass-to-charge ratio M = m/q (m is mass and q is a charge) of ions. The mass analyzing magnet 21, for example, applies a magnetic field in the -y direction to the ion beam to deflect the ion beam in the x direction. The magnetic field intensity of the mass analyzing magnet 21 is adjusted such that ion species having a desired mass-to-charge ratio M can pass through the downstream mass analyzing slit 23.

The mass analyzing lens 22 is provided downstream of the mass analyzing magnet 21 (and upstream of the mass analyzing slit 23), and adjusts a focusing power/defocusing power (or the degree of convergence/degree of defocusing of the ion beam) with respect to the ion beam. The mass analyzing lens 22 adjusts the focusing position of the ion beam passing through the mass analyzing slit 23 in a beam traveling direction (z direction) and adjusts the mass resolution M/dM of the mass analyzing unit 20. In addition, the mass analyzing lens 22 may not be provided in the mass analyzing unit 20.

The mass analyzing slit 23 is provided at a downstream position away from the mass analyzing lens 22. The mass analyzing slit 23 has a rectangular opening 23a having a relatively short width in the x direction and a relatively long height in the y direction. Since the width direction (x direction) of the opening 23a coincides with a beam deflection direction (x direction) by the mass analyzing magnet 21, the width (dimension in the x direction) of the opening 23a mainly contributes to the selection of desired ion species according to the mass-to-charge ratio M in the mass analyzing slit 23.

The mass analyzing slit 23 may make the slit width (the width of the opening 23a) variable in order to adjust the mass resolution. For example, the slit width may be adjusted by configuring the mass analyzing slit 23 with two shield members that are relatively movable in the slit width direction (x direction) and changing the distance between the two shield members in the slit width direction. Additionally, the mass analyzing slit 23 may change the slit width by switching between a plurality of slits having different slit widths.

The beam park device 24 constitutes a beam deflection device that deflects the ion beam by at least one of an electric field and a magnetic field. Specifically, the beam park device 24 is switchable between an irradiation-enabled state in which the ion beam is directed in an irradiation-enabled direction in which the wafer W can be irradiated with the ion beam and an irradiation-disabled state in which the ion beam is directed in an irradiation-disabled direction in which the wafer W cannot be irradiated with the ion beam. In the example of FIG. 2, an arrow directed to the inside of the opening 23a of the mass analyzing slit 23 represents the irradiation-enabled direction, and an arrow directed to the beam dump 26 outside the opening 23a of the mass analyzing slit 23 represents the irradiation-disabled direction. Here, the mass analyzing slit 23 is a slit through which at least a part of the ion beam directed in the irradiation-enabled direction passes, and is provided between the beam park device 24 serving as the beam deflection device and a wafer holding device 52 (FIG. 2) serving as a holding device to be described below.

The beam park device 24 in the irradiation-disabled state temporarily retracts the ion beam from the beamline A and shields the ion beam directed to the downstream implantation processing chamber 16 (or wafer W) with the beam dump 26. That is, the ion beam directed in the irradiation-disabled direction collides with the beam dump 26 outside the opening 23a of the mass analyzing slit 23 and is blocked. The beam park device 24 can be disposed at an optional position on the beamline A but is disposed between the mass analyzing lens 22 and the mass analyzing slit 23 in the shown example. As mentioned above, since a certain distance or more is required between the mass analyzing lens 22 and the mass analyzing slit 23, the space can be efficiently used by disposing the beam park device 24 between the mass analyzing lens 22 and the mass analyzing slit 23. As a result, the beamline A can be shortened, and the entire ion implanter 10 can be downsized as compared to a case where the beam park device 24 is disposed at another location.

The beam park device 24 shown in FIGS. 1 and 2 constitutes a type of beam deflection device that deflects the ion beam by an electric field. The beam park device 24 includes a pair of park electrodes 25 (25a, 25b) and the beam dump 26. The pair of park electrodes 25a and 25b faces each other in the y direction with the beamline A interposed therebetween. The beam park device 24 switches the traveling direction of the ion beam between the irradiation-enabled direction and the irradiation-disabled direction depending on a change in the electric field in the y direction caused by a change in the voltage to be applied to the pair of park electrodes 25a and 25b.

In the example of FIG. 2, when no voltage is applied to the pair of park electrodes 25a and 25b (that is, when the voltage is substantially zero), the irradiation-enabled state is brought about in which a beam of the desired ion species to be used for the ion implantation processing goes straight in the irradiation-enabled direction and passes through the inside of the opening 23a of the mass analyzing slit 23, without being deflected. On the other hand, when a voltage is applied to the pair of park electrodes 25a and 25b (that is, when the voltage has a significant non-zero value), the irradiation-disabled state is brought about in which the beam of the desired ion species to be used for the ion implantation processing is deflected in the -y direction, travels in the irradiation-disabled direction, collides with the beam dump 26 outside the opening 23a of the mass analyzing slit 23, and is shielded.

In the above example, during the non-deflection of the ion beam in which no voltage is applied to the pair of park electrodes 25a and 25b, the ion beam travels in the irradiation-enabled direction, and during the deflection of the ion beam in which a voltage is applied to the pair of park electrodes 25a and 25b, the ion beam travels in the irradiation-disabled direction. However, the ion beam during the non-deflection may travel in the irradiation-disabled direction, and the ion beam during the deflection may travel in the irradiation-enabled direction. In this case, for example, the beam dump 26 may be provided at the position of the opening 23a of the mass analyzing slit 23 in FIG. 2, and the opening 23a of the mass analyzing slit 23 may be provided at the position of the beam dump 26 in FIG. 2. In this case, a configuration downstream of the opening 23a is also provided on the beamline A of the ion beam (deflected) passing through the opening 23a.

Additionally, the ion beam traveling in the irradiation-enabled direction and the ion beam traveling in the irradiation-disabled direction may be deflected by different voltages applied to the pair of park electrodes 25a and 25b. For example, in a case where the irradiation-enabled direction (the direction in which the opening 23a of the mass analyzing slit 23 is located) forms a first deflection angle Θ1 with respect to an incident direction of the ion beam into the beam park device 24, and the irradiation-disabled direction (the direction in which the beam dump 26 is located) forms a second deflection angle Θ2 that is significantly different from the first deflection angle Θ1 with respect to the incident direction of the ion beam into the beam park device 24, the direction in which the beam of the desired ion species travels is switched between the irradiation-enabled direction and the irradiation-disabled direction by switching the voltage to be applied to the pair of park electrodes 25a and 25b between a first voltage V1 that realizes the first deflection angle Θ1 and a second voltage V2 (≠ V1) that realizes the second deflection angle Θ2.

As described above, the facing direction of the pair of park electrodes 25a and 25b is the y direction and is perpendicular to the beam deflection direction (x direction) of the mass analyzing magnet 21. For this reason, the deflection voltage in the y direction to be applied between the pair of park electrodes 25a and 25b does not hinder the selection of the desired ion species according to the mass-to-charge ratio M performed in the x direction by the mass analyzing magnet 21.

In the example of FIG. 2, the first park electrode 25a is disposed above the beamline A in the direction of gravity (the facing direction of the first park electrode 25a and the second park electrode 25b), and the second park electrode 25b is disposed below the beamline A in the direction of gravity. The beam dump 26 provided downstream of the first park electrode 25a and the second park electrode 25b is disposed below the beamline A in the direction of gravity and below the opening 23a of the mass analyzing slit 23 in the direction of gravity. The beam dump 26 is, for example, a wall-like portion of the mass analyzing slit 23 in which the opening 23a is not formed. In addition, the beam dump 26 may be configured separately from the mass analyzing slit 23.

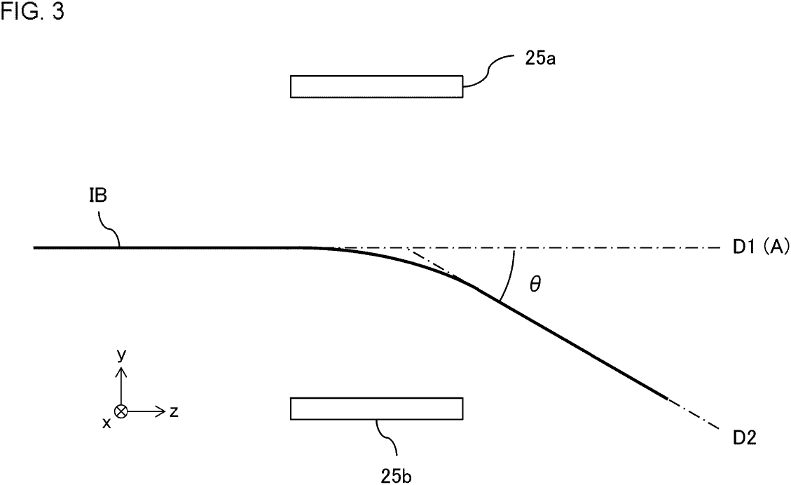

FIG. 3 schematically shows an ion beam IB that is deflected from an irradiation-enabled direction D1 (or the beamline A) to an irradiation-disabled direction D2 by a voltage applied to the pair of park electrodes 25a and 25b. A deflection angle θ of the shown ion beam IB is an angle formed between the irradiation-enabled direction D1 and the irradiation-disabled direction D2. Here, the ion beam IB travels while being bent in a region between the electrodes and in the vicinity thereof in which an electric field between the pair of park electrodes 25a and 25b acts. The deflection angle θ of the ion beam IB is defined as an angle formed by a straight line in the irradiation-enabled direction D1 that goes straight before the ion beam IB is bent, and a straight line in the irradiation-disabled direction D2 that goes straight after the ion beam IB is bent. When the deflection angle θ is too small, there is a risk that a part of the ion beam IB may enter the opening 23a of the mass analyzing slit 23 even in the deflection, and when the deflection angle θ is too large, the mass analyzing slit 23 constituting the beam dump 26 is increased in size. As a result of the study by the present inventor, it is preferable that the deflection angle θ formed by the irradiation-enabled direction D1 and the irradiation-disabled direction D2 is from 2 degrees to 60 degrees. Additionally, the deflection angle θ is more preferably from 3 degrees to 45 degrees, and even more preferably from 5 degrees to 30 degrees.

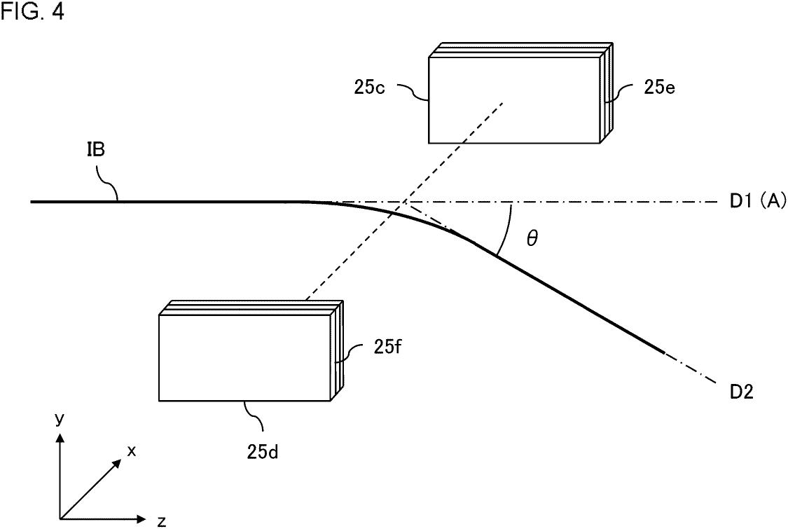

FIG. 4 schematically shows the ion beam IB that is deflected from the irradiation-enabled direction D1 (or the beamline A) to the irradiation-disabled direction D2 by a magnetic field applied between the pair of magnetic poles 25c and 25d. While the beam park device 24 shown in FIGS. 1 to 3 constitutes a type of beam deflection device that deflects the ion beam by an electric field, the beam park device 24 according to a modification example of FIG. 4 constitutes a type of beam deflection device that deflects the ion beam by a magnetic field.

The beam park device 24 includes the pair of magnetic poles 25c and 25d that faces each other in the x direction with the ion beam IB interposed therebetween. Each of the magnetic poles 25c and 25d is a core of a magnetic material such as iron, and coils 25e and 25f are wound around the outer peripheries of the cores. The magnetic poles 25c and 25d and the coils 25e and 25f constitute an electromagnet that causes a magnetic field change in the x direction by changing an electric current to be applied to the coils 25e and 25f. Since the ion beam IB traveling in the z direction receives a Lorentz force in the -y direction due to the magnetic field in the x direction between the magnetic poles 25c and 25d, the traveling direction of the ion beam IB is switchable between the irradiation-enabled direction D1 and the irradiation-disabled direction D2 similarly to FIG. 3. In addition, instead of or in addition to the coils 25e and 25f wound around the magnetic poles 25c and 25d, a coil may be wound around a yoke (not shown) that magnetically connects the pair of magnetic poles 25c and 25d to each other.

In the example of FIG. 4, when a magnetic field in the x direction is not applied between the pair of magnetic poles 25c and 25d, the irradiation-enabled state is brought about in which a beam of the desired ion species to be used for the ion implantation processing goes straight in the irradiation-enabled direction and passes through the inside of the opening 23a of the mass analyzing slit 23, without being deflected. On the other hand, when a magnetic field in the x direction is applied between the pair of magnetic poles 25c and 25d, the irradiation-disabled state is brought about in which the beam of the desired ion species to be used for the ion implantation processing is deflected in the -y direction, travels in the irradiation-disabled direction, collides with the beam dump 26 outside the opening 23a of the mass analyzing slit 23, and is shielded.

In the above example, during the non-deflection of the ion beam in which no magnetic field is applied between the pair of magnetic poles 25c and 25d, the ion beam travels in the irradiation-enabled direction, and during the deflection of the ion beam in which a magnetic field is applied between the pair of magnetic pole 25c and 25d, the ion beam travels in the irradiation-disabled direction. However, the ion beam during the non-deflection may travel in the irradiation-disabled direction, and the ion beam during the deflection may travel in the irradiation-enabled direction. Additionally, the ion beam traveling in the irradiation-enabled direction and the ion beam traveling in the irradiation-disabled direction may be deflected by different magnetic fields applied between the pair of magnetic poles 25c and 25d.

In addition, instead of or in addition to the beam park device 24 according to the embodiment of FIGS. 1 to 3 or the modification example of FIG. 4, the mass analyzing magnet 21 in the mass analyzing unit 20 may be used as a beam deflection device that deflects the ion beam between the irradiation-enabled direction and the irradiation-disabled direction by a magnetic field. As mentioned above, the mass analyzing magnet 21 applies a magnetic field in the -y direction to deflect the ion beam in the x direction, and the ion species having the desired mass-to-charge ratio M pass through the opening 23a of the mass analyzing slit 23 in the irradiation-enabled state. On the other hand, in the irradiation-disabled state, the magnetic field in the y direction of the mass analyzing magnet 21 is changed to deflect an ion beam containing desired ion species to a position in the x direction deviating from the opening 23a of the mass analyzing slit 23. In this case, the beam dump 26 provided at a position deviated from the opening 23a in the y direction in the example of FIG. 2 is provided at a position deviating from the opening 23a in the x direction. Additionally, the ion beam may be deflected between the irradiation-enabled direction and the irradiation-disabled direction by combining the electric field deflection type beam park device 24 as in the embodiment of FIGS. 1 to 3 and the magnetic field deflection type beam park device 24 as in the modification example of FIG. 4.

Hereinafter, the various beam park devices 24 as mentioned above, the mass analyzing magnet 21 in the mass analyzing unit 20 functioning as the beam deflection device, and the like will be collectively referred to as the beam deflection device 24.

In FIGS. 1 and 2, an injector Faraday cup 28 that also functions as a beam blocking mechanism is provided downstream of the mass analyzing slit 23. The injector Faraday cup 28 is capable of being moved into and out of the beamline A by the operation of an injector drive unit 29. The injector drive unit 29 moves the injector Faraday cup 28 in the direction (for example, the y direction) perpendicular to an extending direction (z direction) of the beamline A. As shown by a broken line in FIG. 2, in a case where the injector Faraday cup 28 is disposed on the beamline A, a blocking state is brought about in which the ion beam directed to the downstream side is physically blocked. On the other hand, as shown by a solid line in FIG. 2, in a case where the injector Faraday cup 28 is removed from the beamline A, a non-blocking state is brought about in which the ion beam directed to the downstream side passes through without being physically blocked. In this way, the injector Faraday cup 28 and the injector drive unit 29 function as a beam blocking mechanism that is switchable between a blocking state in which the ion beam is physically blocked and a non-blocking state in which the ion beam is allowed to pass therethrough.

The injector Faraday cup 28 measures the beam current of the ion beam mass-analyzed by the mass analyzing unit 20. By measuring the beam current while changing the magnetic field intensity of the mass analyzing magnet 21, the injector Faraday cup 28 can acquire the mass analysis spectrum of the ion beam. This mass analysis spectrum is used, for example, to calculate the mass resolution of the mass analyzing unit 20.

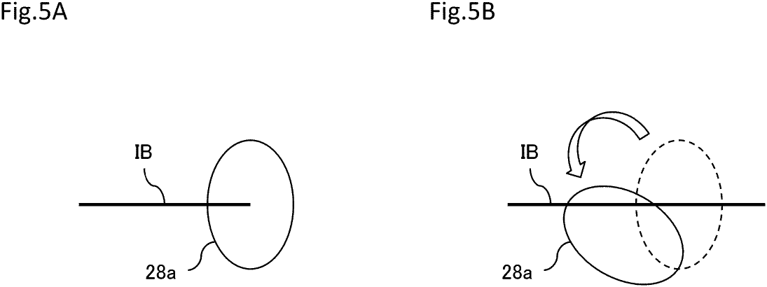

FIG. 5A to FIG. 9B show modification examples of the beam blocking mechanisms. A in each drawing (FIG. 5A or the like) shows a blocking state in which the beam blocking mechanism physically blocks the ion beam IB, and B (FIG. 5B or the like) in each drawing shows a non-blocking state in which the beam blocking mechanism allows the ion beam IB to pass therethrough.

The beam blocking mechanism in FIGS. 5A and 5B is a shielding plate 28a having a disc shape or the like. In the blocking state of FIG. 5A, the shielding plate 28a is disposed on the beamline A and physically blocks the ion beam IB. In the non-blocking state of FIG. 5B, since the shielding plate 28a rotated around a rotation axis in a direction (for example, the x direction) perpendicular to the extending direction (z direction) of the beamline A as indicated by an arrow from the blocking state deviates from the beamline A, the ion beam IB can pass.

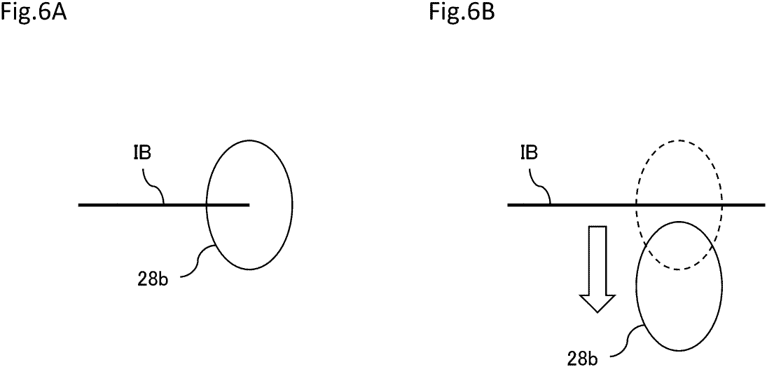

A beam blocking mechanism in FIGS. 6A and 6B is a shielding plate 28b having a disc shape or the like. In the blocking state of FIG. 6A, the shielding plate 28b is disposed on the beamline A and physically blocks the ion beam IB. In the non-blocking state of FIG. 6B, since the shielding plate 28b moved in a direction (for example, the y direction) perpendicular to the extending direction (z direction) of the beamline A as indicated by an arrow from the blocking state deviates from the beamline A, the ion beam IB can pass.

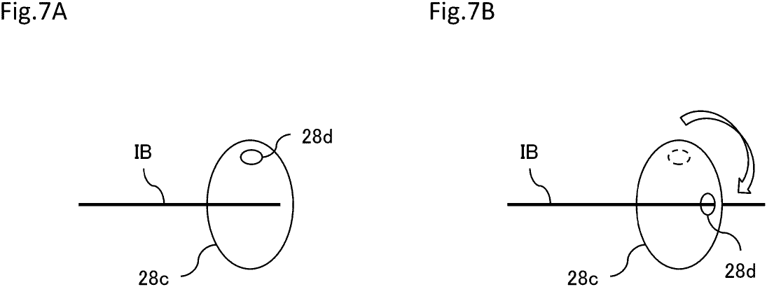

A beam blocking mechanism in FIGS. 7A and 7B is a shielding plate 28c having a disc shape or the like, and a window 28d or a hole through which the ion beam IB can pass is formed at at least one spot of the outer periphery thereof. In the blocking state of FIG. 7A, since the window 28d deviates from the beamline A, a portion of the shielding plate 28c other than the window 28d physically blocks the ion beam IB. In the non-blocking state of FIG. 7B, since the window 28d of the shielding plate 28c rotated around a rotation axis in a direction parallel to the extending direction (z direction) of the beamline A as indicated by an arrow from the blocking state is disposed on the beamline A, the ion beam IB can pass through the window 28d.

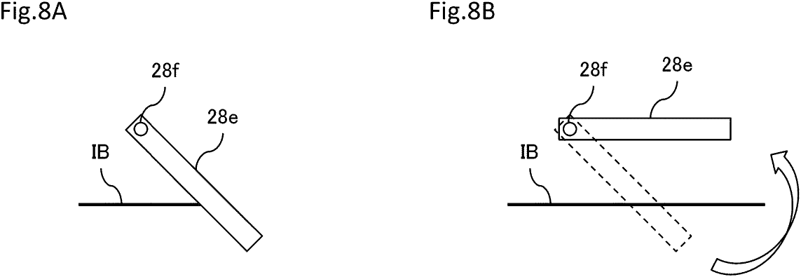

A beam blocking mechanism in FIGS. 8A and 8B is a shielding plate 28e that is a plate rotatable around a rotary shaft 28f in a direction (for example, the x direction) perpendicular to the extending direction (z direction) of the beamline A. In the blocking state of FIG. 8A, the shielding plate 28e is disposed on the beamline A and physically blocks the ion beam IB. In the non-blocking state of FIG. 8B, since the shielding plate 28e rotated around the rotary shaft 28f as indicated by an arrow from the blocking state deviates from the beamline A, the ion beam IB can pass.

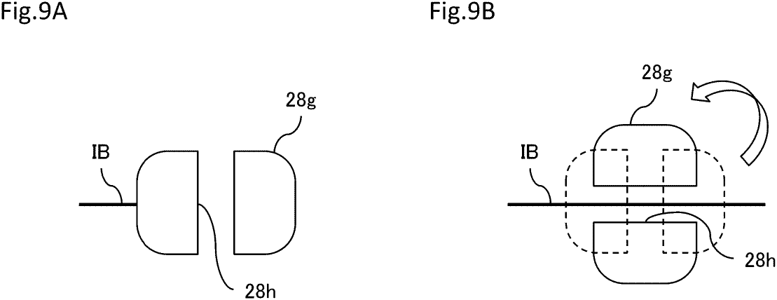

A beam blocking mechanism of FIGS. 9A and 9B is a block-shaped shield member 28g having a passage 28h through which the ion beam IB can pass. The block-shaped shield member 28g is rotatable around a rotation axis in a direction (for example, the x direction) perpendicular to the extending direction (z direction) of the beamline A. In the blocking state of FIG. 9A, since the passage 28h intersects or is perpendicular to the beamline A, a portion of the shield member 28g other than the passage 28h physically blocks the ion beam IB. In the non-blocking state of FIG. 9B, since the passage 28h of the shield member 28g rotated from the blocking state as indicated by an arrow is disposed substantially parallel to the beamline A, the ion beam IB can pass through the passage 28h.

Hereinafter, the beam blocking mechanisms of FIGS. 5 to 9 and the injector Faraday cup 28 of FIGS. 1 and 2 will be collectively referred to as a beam blocking mechanism 28.

In FIGS. 1 and 2, the beam shaping unit 30 includes a focusing/defocusing device such as a focusing/defocusing quadrupole lens (Q lens), and shapes the ion beam that has passed through the mass analyzing unit 20 into a desired cross-sectional shape. The beam shaping unit 30 composed of, for example, an electric field type three-stage quadrupole lens (also referred to as a triplet Q lens) has three quadrupole lenses 30a, 30b, and 30c. By using the three quadrupole lenses 30a, 30b, and 30c, the beam shaping unit 30 can independently adjust the convergence or divergence of the ion beam in the x direction and the y direction. The beam shaping unit 30 may include a magnetic field type lens device or may include a lens device that shapes the ion beam by utilizing both an electric field and a magnetic field.

The beam scanning device 32 performs reciprocating scanning by at least one of an electric field and a magnetic field in a predetermined scanning angle range in the x direction with an ion beam (shaped by the beam shaping unit 30) with which the wafer W is irradiated. As will be described below, the beam scanning device 32 can also be used as a beam deflection device that deflects the ion beam between the irradiation-enabled direction and the irradiation-disabled direction instead of or in addition to the beam park device 24. The beam scanning device 32 includes a pair of scanning electrodes that faces each other in a beam scanning direction (x direction). The pair of scanning electrodes is connected to a variable voltage power supply (not shown), and a voltage to be applied between the pair of scanning electrodes is periodically changed to change an electric field between the electrodes such that the ion beam is deflected at various angles in a zx plane. As a result, the entire scanning range in the x direction is scanned with the ion beam. In FIG. 1, a scanning direction and a scanning range of the ion beam are exemplified by an arrow X, and a plurality of trajectories of the ion beam in the scanning range are exemplified by one-point chain lines.

The beam parallelizing unit 34 adjusts the traveling directions of the ion beam scanned by the beam scanning device 32 to be substantially parallel to the trajectory of the designed beamline A. The beam parallelizing unit 34 includes a plurality of arc-shaped parallelizing lens electrodes in each of which an ion beam passing slit is provided at a central portion in the y direction. The parallelizing lens electrodes are connected to a high-voltage power supply (not shown), and an electric field generated by the applied voltage is made to act on the ion beam to align the traveling directions of the ion beam substantially parallel to the beamline A. In addition, the beam parallelizing unit 34 may be replaced with another type of beam parallelizing device, for example, a magnetic device using a magnetic field. Additionally, an acceleration/deceleration (AD) column (not shown) for accelerating or decelerating the ion beam may be provided downstream of the beam parallelizing unit 34.

The angular energy filter (AEF) 36 analyzes the energy of the ion beam and deflects the ions of having required energy downward (-y direction) at a prescribed angle to guide the ions to the implantation processing chamber 16. The angular energy filter 36 includes an AEF electrode pair for electric field deflection connected to a high-voltage power supply (not shown). In FIG. 2, by applying a positive voltage to an upper (+y side) AEF electrode and applying a negative voltage to a lower (-y side) AEF electrode, an ion beam having a positive charge is deflected downward (in the case of an ion beam having a negative charge, the negative voltage is applied to the upper AEF electrode and the positive voltage is applied to the lower AEF electrode). In addition, the angular energy filter 36 may be composed of a magnetic device for magnetic field deflection or may be composed of a combination of the AEF electrode pair for electric field deflection and the magnetic device for magnetic field deflection.

As described above, the beamline unit 14 supplies the ion beam, with which the wafer W serving as a workpiece is to be irradiated, to the implantation processing chamber 16. The implantation processing chamber 16 includes an energy slit 38, a plasma shower device 40, side cups 42 (42R, 42L), a profiler cup 44, and the beam stopper 46 in order from the upstream side of the beamline A. As shown in FIG. 2, the implantation processing chamber 16 includes a platen driving device 50 that holds one or a plurality of wafers W.

The energy slit 38 is provided downstream of the angular energy filter 36 and analyzes the energy of the ion beam incident into the wafer W together with the angular energy filter 36. The energy slit 38 is an energy defining slit (EDS) which is a slit horizontally long in the beam scanning direction (x direction). The energy slit 38 allows an ion beam having a desired energy value or a desired energy range to pass toward the wafer W, and shields the other ion beams.

The plasma shower device 40 is disposed downstream of the energy slit 38. The plasma shower device 40 supplies low-energy electrons to the ion beam and/or the front surface (wafer processing surface) of the wafer W depending on the amount of beam current of the ion beam and suppresses the accumulation (so-called charge-up) of positive charges on the wafer processing surface generated by ion implantation. The plasma shower device 40 includes, for example, a shower tube through which an ion beam passes and a plasma generating device that supplies electrons into the shower tube.

The side cups 42 (42R, 42L) measure the beam current of the ion beam during ion implantation processing into the wafer W. As shown in FIG. 1, the side cups 42R and 42L are disposed so as to be deviated from the wafer W disposed on the beamline A to the left and right (x direction) and are disposed at positions where the ion beam directed to the wafer W are not blocked during ion implantation. Since the scanning in the x direction is performed with the ion beam beyond a range where the wafer W is located, a part of the scanning beam is incident into the side cups 42R and 42L even during the ion implantation. In this way, the amount of beam current during the ion implantation processing is measured with the side cups 42R and 42L. Since the wafer W serving as a workpiece is not irradiated with the ion beam incident into the side cups 42R and 42L during the ion implantation, the side cups 42R and 42L constitute a second beam current measuring device (a first beam current measuring device will be described below) that measures the beam current of the ion beam directed in the irradiation-disabled direction in which the wafer W cannot be irradiated with the ion beam. In addition, a beam current measuring device such as a Faraday cup may be provided on the beam dump 26 with which the ion beam directed in the irradiation-disabled direction collides, and may serve as the second beam current measuring device.

The profiler cup 44 measures a beam current on the wafer processing surface. The profiler cup 44 is movable in the x direction by the operation of a drive unit 45, is retreated from an implantation region where the wafer W is located during the ion implantation, and is inserted into the implantation region when the wafer W is not located in the implantation region. The profiler cup 44 driven in the x direction can measure the beam current over an entire beam scanning range in the x direction. The profiler cup 44 may include a plurality of Faraday cups that are arranged in the x direction so that the beam currents at a plurality of positions in the beam scanning direction (x direction) can be simultaneously measured. Since the ion beam incident into the profiler cup 44 is incident into the implantation region where the wafer W serving as the workpiece is located during the ion implantation, the profiler cup 44 constitutes a first beam current measuring device that measures the beam current of the ion beam directed in the irradiation-enabled direction in which the wafer W can be irradiated. In addition, a beam current measuring device such as a Faraday cup may be provided on the beam stopper 46 with which the ion beam directed in the irradiation-enabled direction collides, and may serve as the first beam current measuring device.

At least one of the side cups 42 and the profiler cup 44 may include a single Faraday cup for measuring the amount of beam current or may include an angle measuring instrument for measuring the angle information of the ion beam. The angle measuring instrument includes, for example, a slit and a plurality of current detecting units provided apart from the slit in the beam traveling direction (z direction). The angle measuring instrument can measure the angle component or angle distribution of the beam in the slit width direction by measuring the ion beam passing through the slit with the plurality of current detecting units lined up in the slit width direction. At least one of the side cups 42 and the profiler cup 44 may include a first angle measuring instrument capable of measuring angle information in the x direction and/or a second angle measuring instrument capable of measuring angle information in the y direction.

The platen driving device 50 includes a wafer holding device 52, a reciprocating mechanism 54, a twist angle adjustment mechanism 56, and a tilt angle adjustment mechanism 58.

The wafer holding device 52 for holding the wafer W irradiated with the ion beam constitutes a support mechanism that supports the wafer W, and includes an electrostatic chuck as an electrostatic holding mechanism that holds the supported wafer W by electrostatic attraction. The wafer holding device 52 may include a temperature adjusting device for heating or cooling the wafer W into which ions are implanted. The temperature adjusting device may be a heating device that heats the wafer W to a temperature higher than the room temperature by +20° C. or higher, +50° C. or higher, or +100° C. or higher, or may be a cooling device that cools the wafer W to a lower temperature that is a temperature lower than the room temperature by -20° C. or lower, -50° C. or lower, or -100° C. or lower. The temperature of the wafer W affects the concentration distribution (implantation profiler) of ions implanted into the wafer W and the state of crystal defects (implantation damage) formed in the wafer W by the ion implantation. The processing of irradiating the wafer W having a temperature higher than room temperature with the ion beam is also referred to as high-temperature implantation. Additionally, the processing of irradiating the wafer W having a temperature lower than room temperature with the ion beam is also referred to as low-temperature implantation.

The reciprocating mechanism 54 is a drive mechanism that reciprocates the wafer holding device 52 including the support mechanism in a direction intersecting the ion beam. The reciprocating mechanism 54 reciprocates the wafer W held by the wafer holding device 52 in the y direction by reciprocating the wafer holding device 52 including a support mechanism in a reciprocating motion direction (y direction) perpendicular to the beam scanning direction (x direction). In FIG. 2, a direction and a range of the reciprocating motion of the wafer W are exemplified by an arrow Y.

The twist angle adjustment mechanism 56 constituting an implantation angle adjustment mechanism is a mechanism that adjusts the rotation angle of the wafer W, and adjusts the twist angle between an alignment mark provided at an outer peripheral portion of the wafer W and a reference position by rotating the wafer W with a normal line perpendicular to the wafer processing surface as a rotation axis at the center of the wafer processing surface. Here, the alignment mark of the wafer W is, for example, a notch or an orientation flat provided at an outer peripheral portion of the wafer W and serves as a reference for an angular position in the crystal direction of the wafer W or in the circumferential direction of the wafer W. The twist angle adjustment mechanism 56 is provided between the wafer holding device 52 and the reciprocating mechanism 54 and is reciprocated by the reciprocating mechanism 54 together with the wafer holding device 52.

The tilt angle adjustment mechanism 58 constituting the implantation angle adjustment mechanism is a mechanism that adjusts the tilt of the wafer W and adjusts the tilt angle between the traveling direction of the ion beam directed to the wafer processing surface and the normal line of the wafer processing surface. In the example of FIG. 2, out of a plurality of inclination angles of the wafer W, a rotation angle with the axis in the x direction as a center axis of rotation is adjusted as the tilt angle of the wafer W by the tilt angle adjustment mechanism 58. The tilt angle adjustment mechanism 58 is provided between the reciprocating mechanism 54 and an inner wall of the implantation processing chamber 16 and adjusts the tilt angle of the wafer W by rotating the entire platen driving device 50 including the reciprocating mechanism 54 in an R direction (FIG. 2).

The platen driving device 50 holds the wafer W such that the wafer W is movable between the ion implantation position where the wafer W is irradiated with the ion beam and a transfer position where the wafer W is transferred to or from the wafer transfer device 18. That is, the platen driving device 50 constitutes a moving device that moves the wafer holding device 52 between the ion implantation position where the wafer W supported with the wafer holding device 52 is irradiated with the ion beam, and the transfer position where the wafer transfer device 18 can transfer the wafer W to or from the wafer holding device 52. FIG. 2 shows a state in which the wafer W and the wafer holding device 52 are at the ion implantation position, and the wafer holding device 52 holds the wafer W so as to intersect the beamline A. The transfer position of the wafer W corresponds to the position of the wafer holding device 52 when the wafer W is transferred through a transfer port 48 by a transfer mechanism or a transfer robot provided in the wafer transfer device 18.

The beam stopper 46 is provided on the most downstream side of the beamline A and is mounted on, for example, the inner wall of the implantation processing chamber 16. An ion beam in a case where the wafer W and the profiler cup 44 are not present on the beamline A is incident into the beam stopper 46. The beam stopper 46 is disposed near the transfer port 48 that connects the implantation processing chamber 16 and the wafer transfer device 18 to each other, and is provided at a position vertically below (-y direction) the transfer port 48 in the example of FIG. 2.

The ion implanter 10 further includes a control device 60 that controls the overall operation thereof. The control device 60 is realized by the cooperation between hardware resources such as a central arithmetic processing device of a computer, a memory, an input device, an output device, and peripheral units connected to a computer, and software executed using the hardware resources. Regardless of the type and installation location of the computer, each function of the control device 60 may be realized by the hardware resources of a single computer, or may be realized by combining the hardware resources distributed to a plurality of computers. Details of the control device 60 will be described below.

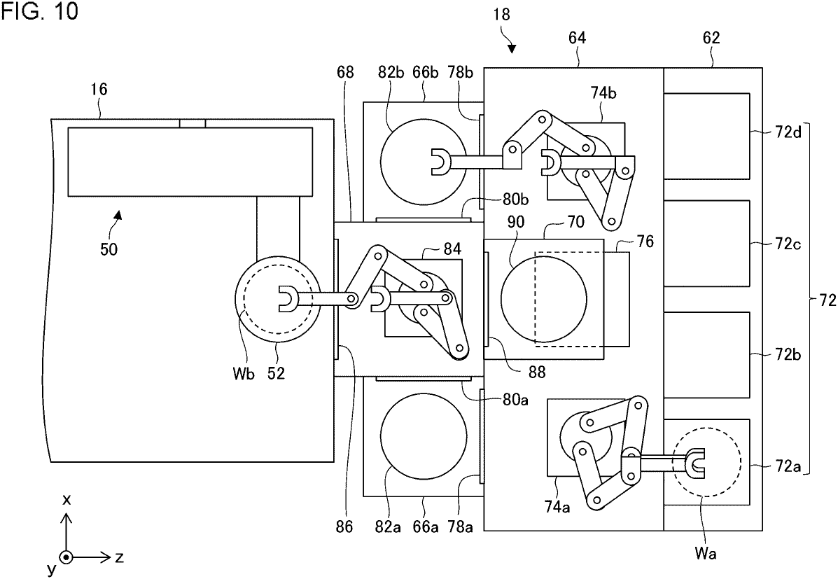

FIG. 10 is a top view showing a schematic configuration of the wafer transfer device 18 serving as a transfer device that transfers the wafer W to or from the wafer holding device 52. The wafer transfer device 18 includes a load port 62, an atmospheric transfer unit 64, a first load lock chamber 66a, a second load lock chamber 66b, an intermediate transfer chamber 68, and a buffer chamber 70.

The load port 62 can receive a plurality of wafer containers 72a, 72b, 72c, 72d (hereinafter, collectively referred to as wafer containers 72). The wafer transfer device 18 transfers an unprocessed wafer Wa in the wafer container 72 to the implantation processing chamber 16 and transfers a processed wafer Wb subjected to the ion implantation processing in the implantation processing chamber 16 out to the wafer container 72.

In the shown state, the processed wafer Wb is inside the implantation processing chamber 16 and is supported with the wafer holding device 52 in front of a processing chamber gate valve 86 (described below) corresponding to the transfer port 48 in FIG. 2. In this state, the processed wafer Wb is transferred from the wafer holding device 52 into the intermediate transfer chamber 68 of the wafer transfer device 18 by an intermediate transfer mechanism 84 of the intermediate transfer chamber 68, which will be described below. In this way, FIG. 10 shows a state where the wafer holding device 52 that supports the processed wafer Wb is located at the transfer position and the wafer can be transferred to or from the wafer transfer device 18. On the other hand, when the ion implantation processing is performed on a wafer in the implantation processing chamber 16, the platen driving device 50 moves the wafer to be processed together with the wafer holding device 52 from the transfer position in FIG. 10 to the ion implantation position in FIG. 2.

The atmospheric transfer unit 64 includes a first atmospheric transfer mechanism 74a, a second atmospheric transfer mechanism 74b, and an alignment device 76. The first atmospheric transfer mechanism 74a is provided between the load port 62 and the first load lock chamber 66a. The first atmospheric transfer mechanism 74a includes, for example, two robot arms for transferring wafers. The first atmospheric transfer mechanism 74a transfers a wafer before the ion implantation processing into the atmospheric transfer unit 64 from a first wafer container 72a or a second wafer container 72b, and transfers the ion implantation-processed wafer out to the first wafer container 72a or the second wafer container 72b outside the atmospheric transfer unit 64. The first atmospheric transfer mechanism 74a transfers the unprocessed wafer before alignment to the alignment device 76 and transfers the aligned unprocessed wafer from the alignment device 76. The first atmospheric transfer mechanism 74a transfers the aligned unprocessed wafer into the first load lock chamber 66a and transfers the ion implantation-processed wafer from the first load lock chamber 66a.

The second atmospheric transfer mechanism 74b is provided between the load port 62 and the second load lock chamber 66b. The second atmospheric transfer mechanism 74b includes, for example, two robot arms for transferring wafers. The second atmospheric transfer mechanism 74b transfers a wafer before the ion implantation processing into the atmospheric transfer unit 64 from a third wafer container 72c or a fourth wafer container 72d, and transfers the ion implantation-processed wafer out to the third wafer container 72c or the fourth wafer container 72d outside the atmospheric transfer unit 64. The second atmospheric transfer mechanism 74b transfers the unprocessed wafer before alignment to the alignment device 76 and transfers the aligned unprocessed wafer from the alignment device 76. The second atmospheric transfer mechanism 74b transfers the aligned unprocessed wafer into the second load lock chamber 66b and transfers the ion implantation-processed wafer from the second load lock chamber 66b.

The alignment device 76 is a device for adjusting the center position and the rotation position (rotation angle) of the wafer. The alignment device 76 detects the alignment mark such as a notch provided on the wafer to adjust the center position and the rotation position of the wafer to desired positions with reference to the alignment mark. Since the center position and the rotation position of the unprocessed wafer transferred into the atmospheric transfer unit 64 from the wafer container 72 are not necessarily aligned, the unprocessed wafer is positioned (aligned) by the alignment device 76 before being transferred into the load lock chambers 66a or 66b. The alignment device 76 is provided at a position between the first atmospheric transfer mechanism 74a and the second atmospheric transfer mechanism 74b. The alignment device 76 is provided, for example, at a position vertically below (-y side) the buffer chamber 70.

Each of the first load lock chamber 66a and the second load lock chamber 66b is provided between the atmospheric transfer unit 64 and the intermediate transfer chamber 68. Each of the first load lock chamber 66a and the second load lock chamber 66b is, for example, adjacent to the atmospheric transfer unit 64 in the z direction and adjacent to the intermediate transfer chamber 68 in the x direction. The intermediate transfer chamber 68 is provided adjacent to the implantation processing chamber 16, for example, in the z direction. The buffer chamber 70 is provided adjacent to the intermediate transfer chamber 68, for example, in the z direction.

The intermediate transfer chamber 68 is maintained in a medium vacuum state of about 10⁻¹ Pa in a steady state. An evacuating device (not shown) composed of a turbo molecular pump or the like is connected to the intermediate transfer chamber 68. Meanwhile, the atmospheric transfer unit 64 is provided under atmospheric pressure and transfers the wafer in the air atmosphere. The first load lock chamber 66a and the second load lock chamber 66b are chambers or spaces that are partitioned to realize wafer transfer between the intermediate transfer chamber 68 maintained in the medium vacuum state and the atmospheric transfer unit 64 under the atmospheric pressure. Each of the first load lock chamber 66a and the second load lock chamber 66b can be evacuated or opened to the air atmosphere during the wafer transfer. A roughing vacuum pump such as an oil rotary vacuum pump or a dry vacuum pump is connected for evacuation of each of the first load lock chamber 66a and the second load lock chamber 66b.

The first load lock chamber 66a includes a first atmospheric-side gate valve 78a provided between the first load lock chamber 66a and the atmospheric transfer unit 64, a first intermediate gate valve 80a provided between the first load lock chamber 66a and the intermediate transfer chamber 68, and a first temperature adjusting device 82a. Similarly, the second load lock chamber 66b includes a second atmospheric-side gate valve 78b provided between the second load lock chamber 66b and the atmospheric transfer unit 64, a second intermediate gate valve 80b provided between the second load lock chamber 66b and the intermediate transfer chamber 68, and a second temperature adjusting device 82b.

In a case where the first load lock chamber 66a is evacuated or opened to the air atmosphere, the first atmospheric-side gate valve 78a and the first intermediate gate valve 80a are closed. In a case where the wafer is transferred between the atmospheric transfer unit 64 and the first load lock chamber 66a, the first atmospheric-side gate valve 78a is opened in a state where the first intermediate gate valve 80a is closed. In a case where the wafer is transferred between the intermediate transfer chamber 68 and the first load lock chamber 66a, the first intermediate gate valve 80a is opened in a state where the first atmospheric-side gate valve 78a is closed.

Similarly, in a case where the second load lock chamber 66b is evacuated or opened to the air atmosphere, the second atmospheric-side gate valve 78b and the second intermediate gate valve 80b are closed. In a case where the wafer is transferred between the atmospheric transfer unit 64 and the second load lock chamber 66b, the second atmospheric-side gate valve 78b is opened in a state where the second intermediate gate valve 80b is closed. In a case where the wafer is transferred between the intermediate transfer chamber 68 and the second load lock chamber 66b, the second intermediate gate valve 80b is opened in a state where the second atmospheric-side gate valve 78b is closed.

The first temperature adjusting device 82a heats or cools the wafer transferred into the first load lock chamber 66a to adjust the wafer temperature. The first temperature adjusting device 82a may heat or cool the wafer before the ion implantation processing to adjust the wafer temperature to a temperature suitable for the ion implantation processing. The first temperature adjusting device 82a may cool or heat the ion implantation-processed wafer to adjust the wafer temperature to room temperature or a temperature close to room temperature.

The second temperature adjusting device 82b heats or cools the wafer transferred into the second load lock chamber 66b to adjust the wafer temperature. The second temperature adjusting device 82b may heat or cool the wafer before the ion implantation processing to adjust the wafer temperature to a temperature suitable for the ion implantation processing. The second temperature adjusting device 82b may cool or heat the ion implantation-processed wafer to adjust the wafer temperature to room temperature or a temperature close to room temperature.

The intermediate transfer chamber 68 includes an intermediate transfer mechanism 84. The intermediate transfer mechanism 84 includes, for example, two robot arms for transferring wafers. The intermediate transfer mechanism 84 transfers the wafer between the intermediate transfer chamber 68 and each of the chambers adjacent to the intermediate transfer chamber 68. The intermediate transfer mechanism 84 transfers the wafer before the ion implantation processing from the first load lock chamber 66a and transfers the ion implantation-processed wafer into the first load lock chamber 66a. The intermediate transfer mechanism 84 transfers the wafer before the ion implantation processing from the second load lock chamber 66b and transfers the ion implantation-processed wafer into the second load lock chamber 66b. The intermediate transfer mechanism 84 transfers the wafer before the ion implantation processing into the implantation processing chamber 16 and transfers the ion implantation-processed wafer from the implantation processing chamber 16. The intermediate transfer mechanism 84 transfers the wafer before the ion implantation processing or the ion implantation-processed wafer into the buffer chamber 70 and transfers the wafer before the ion implantation processing or the ion implantation-processed wafer from the buffer chamber 70.

A processing chamber gate valve 86 is provided between the implantation processing chamber 16 and the intermediate transfer chamber 68. The processing chamber gate valve 86 is opened in a case where the wafer is transferred between the implantation processing chamber 16 and the intermediate transfer chamber 68. The processing chamber gate valve 86 is closed in a case where the ion implantation processing is performed on the wafer in the implantation processing chamber 16.

The buffer chamber 70 is a chamber for temporarily storing the wafer transferred into the intermediate transfer chamber 68. The buffer chamber 70 includes a buffer chamber gate valve 88 and a third temperature adjusting device 90. The buffer chamber gate valve 88 provided between the intermediate transfer chamber 68 and the buffer chamber 70 is opened in a case where a wafer is transferred between the intermediate transfer chamber 68 and the buffer chamber 70, and is closed in a case where the third temperature adjusting device 90 adjusts the wafer temperature in the buffer chamber 70.

The third temperature adjusting device 90 heats or cools the wafer transferred into the buffer chamber 70 to adjust the temperature of the wafer. The third temperature adjusting device 90 may heat or cool the wafer before the ion implantation processing to adjust the wafer temperature to a temperature suitable for the ion implantation processing. The third temperature adjusting device 90 may cool or heat the ion implantation-processed wafer to adjust the wafer temperature to room temperature or a temperature close to room temperature.

Although an example of the wafer transfer device 18 is shown in FIG. 10, the present invention can be applied to any other type of transfer device. For example, the present invention can also be applied to a wafer transfer device including a rotating arm as shown in Japanese Unexamined Patent Publication No. 2006-156762.

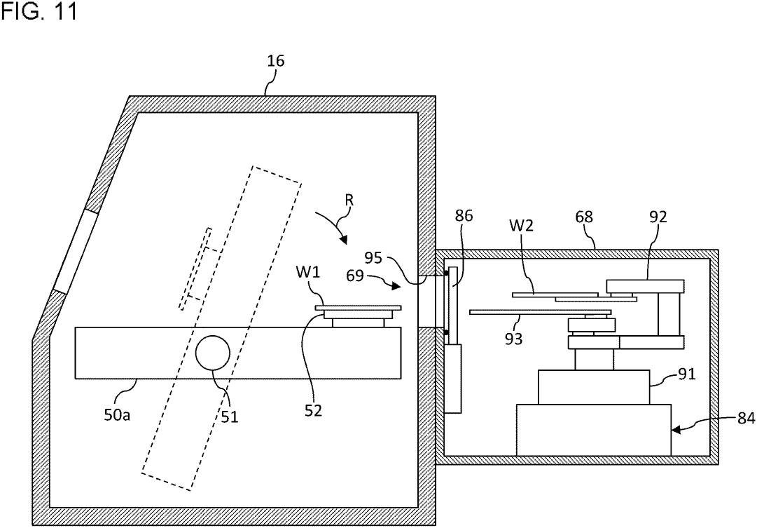

FIGS. 11 to 14 are views schematically showing a swap operation performed by the intermediate transfer mechanism 84. FIG. 11 shows a state before wafer replacement performed by the intermediate transfer mechanism 84. As the moving device 50a of the platen driving device 50 rotates around a rotary shaft 51 in the direction of an arrow R from the ion implantation position indicated by a dotted line to the transfer position indicated by a solid line, a state is brought about in which a first wafer W1 subjected to the ion implantation processing in the implantation processing chamber 16 can be transferred. An intermediate transfer chamber-implantation processing chamber communication mechanism 69 between the implantation processing chamber 16 and the intermediate transfer chamber 68 is provided with a communication port 95 that connects the implantation processing chamber 16 and the intermediate transfer chamber 68 to each other, and a processing chamber gate valve 86 that closes the communication port 95. A second wafer W2 before the ion implantation processing is held by an upper arm 92 of the intermediate transfer mechanism 84 in the intermediate transfer chamber 68.

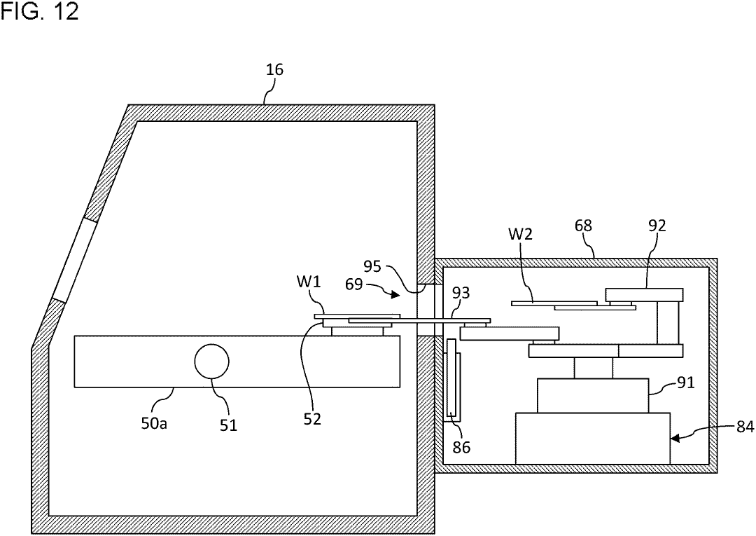

FIG. 12 shows an aspect in which the first wafer W1 is held by the intermediate transfer mechanism 84. When the processing chamber gate valve 86 is opened and the implantation processing chamber 16 and the intermediate transfer chamber 68 communicate with each other, the lower arm 93 of the intermediate transfer mechanism 84 extends into the implantation processing chamber 16, and the first wafer W1 is held by a holding unit at a tip of the lower arm 93.

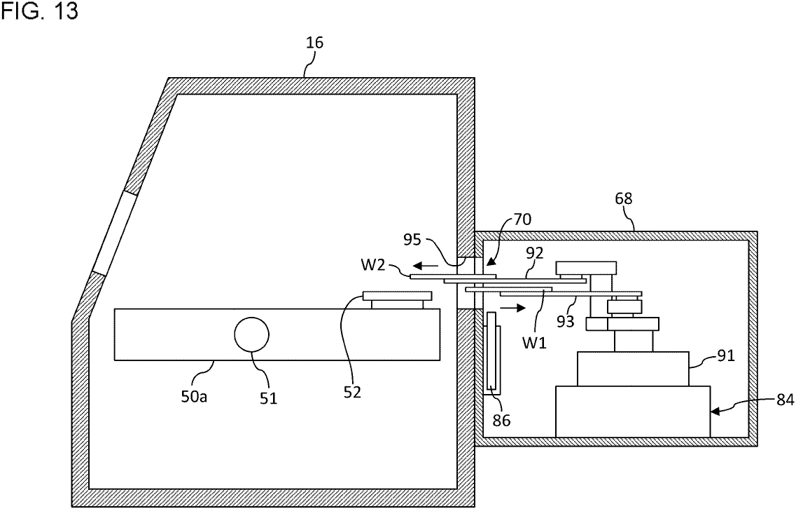

FIG. 13 shows an aspect in which the first wafer W1 and the second wafer W2 are swapped by the intermediate transfer mechanism 84. The intermediate transfer mechanism 84 transfers the first wafer W1 from the implantation processing chamber 16 into the intermediate transfer chamber 68 by contracting the lower arm 93 toward the intermediate transfer chamber 68 side, and transfers the second wafer W2 from the intermediate transfer chamber 68 into the implantation processing chamber 16 by extending the upper arm 92 to the implantation processing chamber 16 side. In this case, a swap operation in which the first wafer W1 and the second wafer W2 pass each other is realized in a positional relationship in which the second wafer W2 is on the upper side and the first wafer W1 is on the lower side.

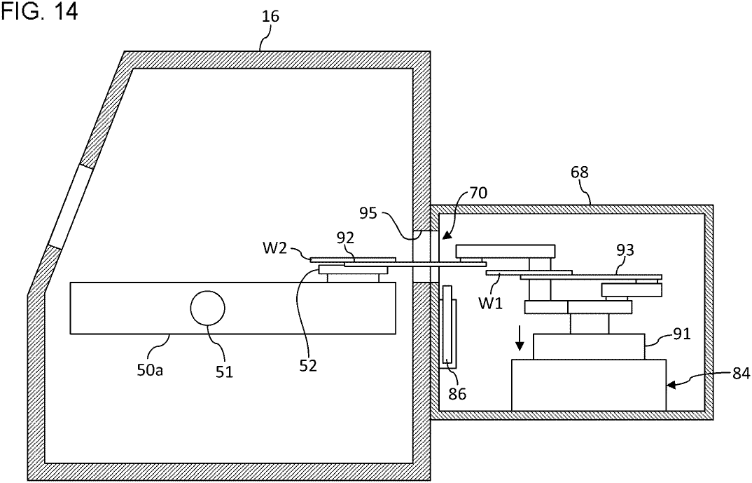

FIG. 14 shows an aspect in which the second wafer W2 is placed on the wafer holding device 52 of the moving device 50a by the intermediate transfer mechanism 84. The intermediate transfer mechanism 84 contracts the lower arm 93 to accommodate the first wafer W1 in the intermediate transfer chamber 68, and extends the upper arm 92 to a placement position (transfer position) of the second wafer W2, and then lowers an intermediate transfer body portion 91 to lower the positions of the upper arm 92 and the lower arm 93. After the second wafer W2 is placed on the wafer holding device 52, the upper arm 92 is contracted to close the processing chamber gate valve 86, whereby the replacement between the first wafer W1 and the second wafer W2 is completed. After that, the moving device 50a rotates around the rotary shaft 51 from the transfer position to an ion implantation position, and ion implantation into the second wafer W2 is started.

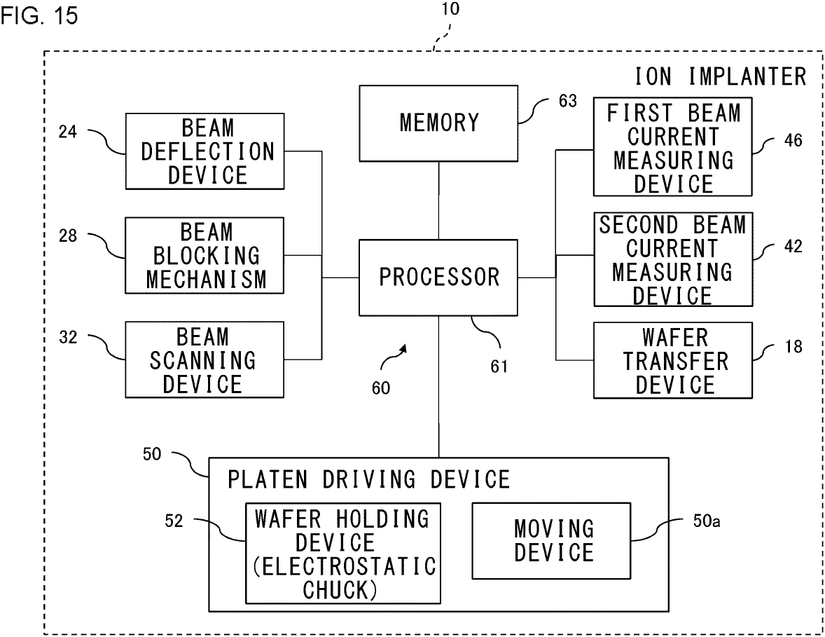

FIG. 15 is a functional block diagram of the ion implanter 10. The control device 60 of the ion implanter 10 includes a processor 61 and a memory 63. The processor 61 controls the respective units of the ion implanter 10, such as the beam deflection device 24 (the beam park device 24 and the like), the beam blocking mechanism 28 (the injector Faraday cup 28 and the like), the beam scanning device 32, a first beam current measuring device 46 (the beam stopper 46 and the like configured as a beam current measuring device), a second beam current measuring device 42 (the side cup 42 and the like), the wafer transfer device 18, the platen driving device 50 (including the wafer holding device 52 having an electrostatic chuck, and the moving device 50a capable of moving the wafer holding device 52). The memory 63 stores a program to be executed by the processor 61. The processor 61 controls the respective units of the ion implanter 10 on the basis of the program stored in the memory 63, and executes the following series of steps.

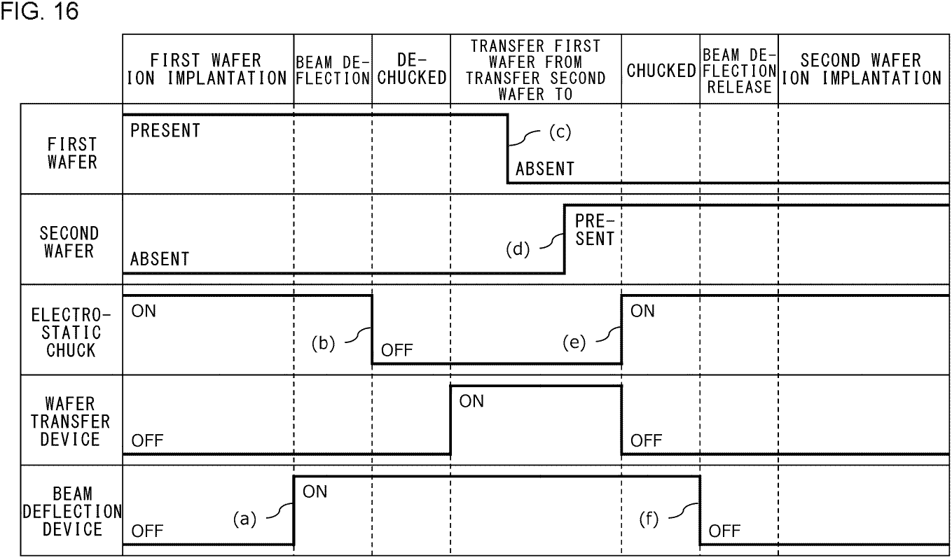

FIG. 16 is a timing chart schematically showing a basic operation of the ion implanter 10 to be executed by the processor 61 on the basis of the program stored in the memory 63. Respective rows in FIG. 16 show a first wafer and a second wafer as workpieces of the ion implanter 10, and respective units directly related to the basic operation of the ion implanter 10, specifically, an electrostatic chuck (the wafer holding device 52), the wafer transfer device 18, and the beam deflection device 24. Additionally, respective columns in FIG. 16 show a series of steps constituting the basic operation of the ion implanter 10 over time.

“PRESENT” and “ABSENT” in the “FIRST WAFER” in a first row of FIG. 16 indicate the presence and absence of the first wafer on the wafer holding device 52. “PRESENT” and “ABSENT” in the “SECOND WAFER” in a second row of FIG. 16 indicate the presence and absence of the second wafer on the wafer holding device 52. “ON” and “OFF” in the “ELECTROSTATIC CHUCK” in a third row of FIG. 16 indicate operating states of the electrostatic chuck of the wafer holding device 52. During “ON”, the electrostatic chuck holds the wafer supported on the wafer holding device 52 by electrostatic attraction, and during “OFF” when the electrostatic chuck is not operating, the wafer can be transferred (transferred to or from) between the wafer holding device 52 and the wafer transfer device 18.

“ON” and “OFF” in the “WAFER TRANSFER DEVICE” in a fourth row of FIG. 16 indicate operating states of the wafer transfer device 18. During “ON”, the wafer transfer device 18 transfers the wafer (transfers the wafer to or from) between the wafer transfer device 18 and the wafer holding device 52, and during “OFF”, the wafer transfer device 18 does not transfer the wafer between the wafer transfer device 18 and the wafer holding device 52. However, even in a case where the wafer transfer device 18 is “OFF”, the entire wafer transfer device 18 does not stop, and processing such as transfer inside the wafer transfer device 18 described with reference to FIG. 10 and the transfer of the wafer to or from the outside of the ion implanter 10 in the load port 62 are performed.

“ON” and “OFF” in the “BEAM DEFLECTION DEVICE” in a fifth row of FIG. 16 indicate operating states of the beam deflection device 24. During “ON”, the beam deflection device 24 deflects the ion beam in the irradiation-disabled direction, and during “OFF” when the beam deflection device 24 is not operating, the ion beam travels in the irradiation-enabled direction.

In the step of “FIRST WAFER ION IMPLANTATION” in a first column of FIG. 16, ion implantation processing is executed on the first wafer at the ion implantation position (FIG. 2) in the implantation processing chamber 16. In this case, since the “FIRST WAFER” in the first row is “PRESENT”, the first wafer is on the wafer holding device 52, and since the “ELECTROSTATIC CHUCK” in the third row is “ON”, the first wafer is held by an electrostatic chuck. Then, since the “BEAM DEFLECTION DEVICE” in the fifth row is set to “OFF”, the first wafer held by the electrostatic chuck is irradiated with the ion beam traveling in the irradiation-enabled direction.

In the step (a) of “BEAM DEFLECTION” in a second column of FIG. 16, after the first wafer serving as the first workpiece held by the electrostatic chuck (wafer holding device 52) is irradiated with the ion beam (step of “FIRST WAFER ION OMPLANTATION”), the beam deflection device 24 is switched to the irradiation-disabled state. In this case, the “BEAM DEFLECTION DEVICE” in the fifth row is switched from “OFF” to “ON”, and the ion beam deflected in the irradiation-disabled direction by the beam deflection device 24 collides with the beam dump 26 or the like in FIG. 2 and is shielded. As a result, the irradiation-disabled state is brought about in which the first wafer held on the electrostatic chuck is not irradiated with the ion beam.

In the step (b) of “DECHUCKED” in a third column of FIG. 16, subsequently to the step (a), the holding of the first wafer by the electrostatic chuck is released. For this reason, the state of the “ELECTROSTATIC CHUCK” in the third row is switched from “ON” to “OFF”. Since the first wafer is not irradiated with the ion beam in the step (a), the holding of the first wafer by the electrostatic chuck can be quickly released. In addition, in the step (b), after the moving device 50a (platen driving device 50) moves the wafer holding device 52 supporting the first wafer from the ion implantation position (FIG. 2) to the transfer position (FIG. 10), the electrostatic chuck releases the holding of the first wafer. While the wafer holding device 52 is moved from the ion implantation position to the transfer position by the moving device 50a, the first wafer is held by the electrostatic chuck. Therefore, the moving first wafer can be prevented from falling off in the implantation processing chamber 16.

In the step of “TRANSFER FIRST WAFER FROM/TRANSFER SECOND WAFER TO” in a fourth column of FIG. 16, after the processed first wafer is transferred from the wafer holding device 52 by the wafer transfer device 18, an unprocessed second wafer (second workpiece) different from the first wafer is transferred to the wafer holding device 52 by the wafer transfer device 18. Specifically, in the step (c) of the “TRANSFER FIRST WAFER FROM”, subsequently to the step (b), the first wafer, which is released from being held by the electrostatic chuck and is at the transfer position, is transferred from the wafer holding device 52 by the wafer transfer device 18 (intermediate transfer mechanism 84). For this reason, the state of the “FIRST WAFER” in the first row is switched from “PRESENT” to “ABSENT”. Additionally, in the step (d) of “TRANSFER SECOND WAFER TO”, subsequently to the step (c), the unprocessed second wafer is transferred to the wafer holding device 52 at the transfer position by the wafer transfer device 18 (intermediate transfer mechanism 84). For this reason, the state of the “SECOND WAFER” in the second row is switched from “ABSENT” to “PRESENT”.

In the step (e) of “CHUCKED” in a fifth column of FIG. 16, subsequently to the step (d), the electrostatic chuck of the wafer holding device 52 holds the second wafer. For this reason, the state of the “ELECTROSTATIC CHUCK” in the third row is switched from “OFF” to “ON”. In addition, in the step (e), after the electrostatic chuck of the wafer holding device 52 holds the second wafer at the transfer position, the moving device 50a (platen driving device 50) moves the second wafer together with the wafer holding device 52 from the transfer position (FIG. 10) to the ion implantation position (FIG. 2). Since the second wafer is already held by the electrostatic chuck before the wafer holding device 52 is moved from the transfer position to the ion implantation position by the moving device 50a, the moving second wafer can be prevented from falling off in the implantation processing chamber 16. In the step (e) of FIG. 16, the switching of the “ELECTROSTATIC CHUCK” from “OFF” to “ON” and the switching of the “WAFER TRANSFER DEVICE” from “ON” to “OFF” are simultaneously shown. However, the timings of these switchings may be different from each other.

In the step (f) of “BEAM DEFLECTION RELEASE” in a sixth column of FIG. 16, subsequently to the step (e), the beam deflection device 24 is switched to the irradiation-enabled state. In this case, after the “BEAM DEFLECTION DEVICE” in the fifth row is switched from “ON” to “OFF”, and the ion beam travels in the irradiation-enabled direction without being deflected by the beam deflection device 24 and passes through the opening 23a of the mass analyzing slit 23, the irradiation-enabled state is brought about in which the second wafer at the ion implantation position is irradiated with the ion beam. In the step of “SECOND WAFER ION IMPLANTATION” in a seventh column of FIG. 16, subsequently to the step (f), ion implantation processing is executed on the second wafer at the ion implantation position in the implantation processing chamber 16. Since the “BEAM DEFLECTION DEVICE” in the fifth row is switched to “OFF” in the step (f), the second wafer held by the electrostatic chuck in the step (e) is irradiated with the ion beam traveling in the irradiation-enabled direction.

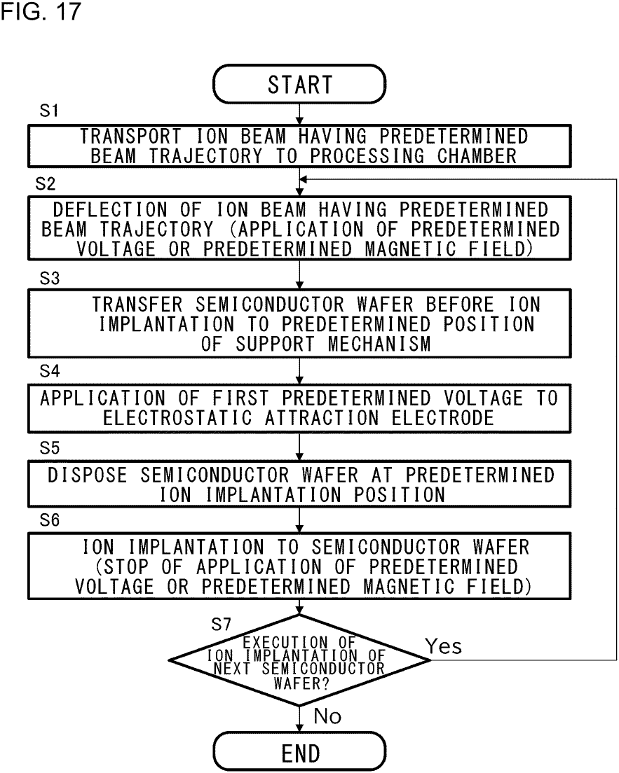

FIG. 17 is a flowchart of a basic operation of the ion implanter 10 to be executed by the processor 61 on the basis of the program stored in the memory 63. “S” in the flowchart means step or processing. In S1, an ion beam having a predetermined beam trajectory (beamline A) which is generated by the ion generation device 12 and shaped by the beamline unit 14 is transported to the processing chamber (implantation processing chamber 16). In this case, the wafer W to be processed has not yet been transferred to the inside of the implantation processing chamber 16. In S2 corresponding to the step (a) in FIG. 16, the beam deflection device 24 deflects the ion beam in the irradiation-disabled direction. Therefore, the ion beam collides with the beam dump 26 or the like in FIG. 2 and is shielded, resulting in a state in which the inside of the implantation processing chamber 16 is not irradiated with the ion beam.

In S3 corresponding to the step (d) in FIG. 16, a semiconductor wafer before the ion implantation is transferred by the wafer transfer device 18 to a predetermined position of the support mechanism of the wafer holding device 52 at the transfer position (FIG. 14). In S4 corresponding to the step (e) in FIG. 16, a first predetermined voltage is applied to an electrostatic attraction electrode of the electrostatic chuck of the wafer holding device 52, and the semiconductor wafer transferred in S3 is held at the transfer position. In S5 similarly corresponding to the step (e) in FIG. 16 and subsequent to S4, the moving device 50a (platen driving device 50) moves the semiconductor wafer together with the wafer holding device 52 from the transfer position (FIG. 14) to the ion implantation position.

In S6 corresponding to the step (f) and the “SECOND WAFER ION IMPLANTATION” of FIG. 16, the ion beam traveling in the irradiation-enabled direction due to the stop of the beam deflection device 24 passes through the opening 23a of the mass analyzing slit 23, and the semiconductor wafer at the ion implantation position is irradiated with the ion beam. In S7, the presence or absence of the next semiconductor wafer to be subjected to the ion implantation processing is determined. In a case where the result is determined to be Yes in S7, the process returns to S2. In addition, although not shown, after the beam deflection device 24 is switched to the irradiation-disabled state in S2 and before S3, the semiconductor wafer subjected to the ion implantation processing in the last S6 is released from being held by the electrostatic chuck in the “DECHUCKED” step (b) in FIG. 16 and the semiconductor wafer is transferred from the wafer holding device 52 by the wafer transfer device 18 in the “TRANSFER FIRST WAFER FROM” step (c) in FIG. 16.

Subsequently, modification examples of the basic operation of the above-mentioned ion implanter 10 will be described.

In a first modification example, the beam blocking mechanism 28 is used. The processor 61 switches the beam blocking mechanism 28 to the blocking state after the “BEAM DEFLECTION” step (a) in FIG. 16, and switches the beam blocking mechanism 28 to the non-blocking state before the “BEAM DEFLECTION RELEASE” step (f) in FIG. 16. Since the ion beam is deflected in the irradiation-disabled direction in the “BEAM DEFLECTION” step (a), basically, the inside of the implantation processing chamber 16 is not irradiated with the ion beam until the “BEAM DEFLECTION RELEASE” step (f). However, since there is also a possibility that a malfunction may occur in the beam deflection device 24, the ion beam is preferable to be physically and reliably blocked by bringing the beam blocking mechanism 28 into the blocking state.

In a second modification example, in addition to the beam blocking mechanism 28, the first beam current measuring device 46 and/or the second beam current measuring device 42 is used. In a case where a beam current equal to or greater than a first predetermined value is not measured with the first beam current measuring device 46 (such as the beam stopper 46 or the like configured as a beam current measuring device) that measures a beam current of an ion beam directed in the irradiation-enabled direction, the processor 61 may make a determination of being in the irradiation-disabled state to switch the beam blocking mechanism 28 to the blocking state. That is, in a case where the beam current measured with the first beam current measuring device 46 is smaller than the first predetermined value, there is a risk that the intensity of the ion beam to be used for the ion implantation processing in the implantation processing chamber 16 is insufficient. Therefore, the beam blocking mechanism 28 is switched to the blocking state, and then the ion implantation processing is interrupted or stopped. In addition to or instead of the first beam current measuring device 46, in a case where the beam current of the first predetermined value or more or the beam current of a predetermined value equivalent to the first predetermined value or more is not measured with the second beam current measuring device 42 (side cups 42 or the like), the processor 61 may make a determination of being in the irradiation-disabled state to switch the beam blocking mechanism 28 to the blocking state.

In a case where a beam current equal to or greater than a second predetermined value is measured with the second beam current measuring device 42 (side cups 42 or the like) that measures the beam current of the ion beam directed in the irradiation-disabled direction, the processor 61 may make a determination of being in the irradiation-disabled state to switch the beam blocking mechanism 28 to the blocking state. That is, in a case where the beam current measured with the second beam current measuring device 42 is equal to or greater than the second predetermined value, there is a risk that the intensity of the ion beam that is not used for the ion implantation processing in the implantation processing chamber 16 is excessive. Therefore, the beam blocking mechanism 28 is switched to the blocking state, and then the ion implantation processing is interrupted or stopped. In addition, the second predetermined value is preferably set such that the beam current density converted from the second predetermined value is greater than the beam current density converted from the first predetermined value.

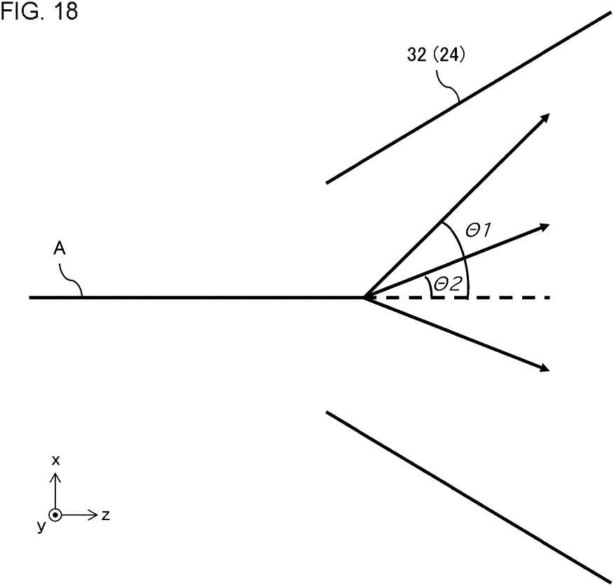

In a third modification example, the beam scanning device 32 is also used as the beam deflection device 24. For example, the beam scanning device 32 realizes the function of the beam deflection device 24 instead of or in addition to the beam park device 24 that has functioned as the beam deflection device 24 in FIGS. 1 and 2. In this case, the beam deflection device 24 and the beam scanning device 32 are the same device. FIG. 18 schematically shows an example in which a beam scanning function as the beam scanning device 32 and a beam deflection function as the beam deflection device 24 are realized by one beam scanning device 32.

In a case where an original beam scanning function is realized, the beam scanning device 32 performs the reciprocating scanning in the predetermined scanning angle range in the x direction with the ion beam with which the wafer W is irradiated. Here, the scanning angle range is an angle range including the irradiation-enabled direction (the direction of the beamline A that can reach a wafer), and a shown θ2 is a maximum scanning angle formed between an outermost angle of the scanning angle range and a reference trajectory direction (the direction of the beamline A in a non-scanning state in which a voltage to be applied between a pair of scanning electrodes of the beam scanning device 32 is substantially zero). In other words, the scanning angle range of the beam scanning device 32 is a range of ±θ2 with respect to the reference trajectory direction.

On the other hand, in a case where the beam scanning device 32 functions as the beam deflection device 24, the ion beam is deflected in the irradiation-disabled direction outside the scanning angle range. Here, a deflection angle θ1 of the ion beam is an angle formed between the irradiation-disabled direction and the reference trajectory direction, and is greater than the maximum scanning angle θ2 (θ1 > θ2). Since the wafer W is not disposed on the path of the ion beam deflected by the deflection angle θ1, the deflection angle θ1 is set to the irradiation-disabled direction in which the wafer W cannot be irradiated with the ion beam. In addition, the beam scanning device 32 functioning as the beam deflection device 24 may deflect the ion beam at a deflection angle of -θ1. Additionally, a beam dump or the like may be provided on the path of the ion beam deflected at the deflection angle θ1 (or -θ1) such that the ion beam collides with the beam dump or the like and is shielded.

In the steps of “FIRST WAFER ION IMPLANTATION” and “SECOND WAFER ION IMPLANTATION” in the basic operation of FIG. 16, the beam scanning device 32 realizes the original beam scanning function and performs the reciprocating scanning in a scanning angle range (-θ2 to +θ2) with the ion beam with which the wafer W is irradiated. Additionally, in the steps (a) to (e) of “BEAM DEFLECTION” to “CHUCKED” in the basic operation of FIG. 16, the beam scanning device 32 functions as the beam deflection device 24, and deflects the ion beam in the irradiation-disabled direction (θ1 or -θ1) outside the scanning angle range.

According to the above-described embodiment and/or modification examples, since the irradiation-disabled state during the replacement of a wafer in the steps (a) to (e) of FIG. 16 and the irradiation-enabled state when the wafer is irradiated with the ion beam in the “FIRST WAFER ION IMPLANTATION” and the “SECOND WAFER ION IMPLANTATION” in FIG. 16 can be quickly switched therebetween by the beam deflection device 24 that deflects the ion beam by at least one of an electric field and a magnetic field, the replacement time of the wafers can be shortened.

The present invention has been described above on the basis of the embodiment. The embodiment is an example, and it will be understood by those skilled in the art that various modification examples are possible for the combinations of the respective components and the respective processes and that such modification examples are also within the scope of the present invention.

In addition, the functional configurations of the respective devices described in the embodiment can be realized by hardware resources or software resources or by the cooperation between the hardware resources and the software resources. Processors, ROMs, RAMs, and other LSIs can be used as the hardware resources. Programs such as operating systems and applications can be used as the software resources.

It should be understood that the invention is not limited to the above-described embodiment, but may be modified into various forms on the basis of the spirit of the invention. Additionally, the modifications are included in the scope of the invention.

What is claimed is:

1. An ion implanter comprising:
a beam deflection device that deflects an ion beam by at least one of an electric field and a magnetic field, and that is switchable between an irradiation-enabled state in which the ion beam is directed in an irradiation-enabled direction in which a workpiece is capable of being irradiated with the ion beam, and an irradiation-disabled state in which the ion beam is directed in an irradiation-disabled direction in which the workpiece is incapable of being irradiated with the ion beam;
a holding device that holds the workpiece to be irradiated with the ion beam;
a transfer device that transfers the workpiece to or from the holding device;
a processor that controls the beam deflection device, the holding device, and the transfer device; and
a memory in which a program is stored,
wherein on the basis of the program, the processor executes
(a) switching the beam deflection device to the irradiation-disabled state after a first workpiece held on the holding device is irradiated with the ion beam;
(b) releasing the holding of the first workpiece on the holding device, subsequently to the step (a);
(c) transferring the first workpiece from the holding device with the transfer device, subsequently to the step (b);
(d) transferring a second workpiece different from the first workpiece to the holding device with the transfer device, subsequently to the step (c);
(e) holding the second workpiece on the holding device, subsequently to the step (d); and
(f) switching the beam deflection device to the irradiation-enabled state, subsequently to the step (e).

2. The ion implanter according to claim 1,
wherein the beam deflection device includes a pair of electrodes facing each other with the ion beam interposed therebetween and is switchable between the irradiation-enabled state and the irradiation-disabled state depending on an electric field change caused by a change in a voltage to be applied to the pair of electrodes.

3. The ion implanter according to claim 1,
wherein the beam deflection device includes a pair of magnetic poles facing each other with the ion beam interposed therebetween, a yoke that magnetically connects the pair of magnetic poles to each other, and a coil that is wound around at least one of the magnetic poles and the yoke, and is switchable between the irradiation-enabled state and the irradiation-disabled state depending on a magnetic field change caused by a change in a current to be applied to the coil.

4. The ion implanter according to claim 1,
wherein a slit is provided between the beam deflection device and the holding device, the slit allows at least a part of the ion beam directed in the irradiation-enabled direction to pass therethrough, and
the ion beam directed in the irradiation-disabled direction collides with an outside of the slit and is blocked.

5. The ion implanter according to claim 1,
wherein a deflection angle formed between the irradiation-enabled direction and the irradiation-disabled direction is from 2 degrees to 60 degrees.

6. The ion implanter according to claim 5,
wherein the deflection angle formed between the irradiation-enabled direction and the irradiation-disabled direction is from 3 degrees to 45 degrees.

7. The ion implanter according to claim 6,
wherein the deflection angle formed between the irradiation-enabled direction and the irradiation-disabled direction is from 5 degrees to 30 degrees.

8. The ion implanter according to claim 1,
wherein the holding device includes a support mechanism that supports the workpiece,
the support mechanism includes an electrostatic holding mechanism that holds the workpiece supported with the support mechanism by electrostatic attraction, and
wherein a moving device is provided, the moving device moves the support mechanism between an ion implantation position where the workpiece supported with the support mechanism is irradiated with the ion beam and a transfer position where the transfer device is capable of transferring the workpiece to or from the support mechanism.

9. The ion implanter according to claim 8,
wherein in the steps (b) and (c), the processor moves the support mechanism, which supports the first workpiece, from the ion implantation position to the transfer position with the moving device, and then releases the holding of the first workpiece with the electrostatic holding mechanism, and transfers the first workpiece from the support mechanism with the transfer device.

10. The ion implanter according to claim 8,
wherein in the steps (d) and (e), the processor transfers the second workpiece with the transfer device to the support mechanism moved with the moving device to the transfer position, and holds the second workpiece with the electrostatic holding mechanism, and then moves the support mechanism from the transfer position to the ion implantation position with the moving device.

11. The ion implanter according to claim 1, further comprising:
a beam scanning device that scans a predetermined scanning angle range by at least one of the electric field and the magnetic field with the ion beam with which the workpiece is irradiated.

12. The ion implanter according to claim 11,
wherein the beam deflection device and the beam scanning device are the same device,
the scanning angle range is an angle range including the irradiation-enabled direction, and
a maximum scanning angle that is formed between an outermost angle of the scanning angle range and a reference trajectory direction in a state in which scanning is not performed with the ion beam is smaller than a deflection angle that is formed between the irradiation-disabled direction and the reference trajectory direction.

13. The ion implanter according to claim 1, further comprising:
a beam blocking mechanism that is switchable between a blocking state in which the ion beam is physically blocked and a non-blocking state in which the ion beam is passed.

14. The ion implanter according to claim 13,
wherein the processor switches the beam blocking mechanism to the blocking state after the step (a) and switches the beam blocking mechanism to the non-blocking state before the step (f).

15. The ion implanter according to claim 13, further comprising:
a first beam current measuring device that measures a beam current of the ion beam directed in the irradiation-enabled direction,
wherein the processor determines that the beam deflection device is in the irradiation-disabled state and switches the beam blocking mechanism to the blocking state in a case where a beam current equal to or greater than a first predetermined value is not measured with the first beam current measuring device.

16. The ion implanter according to claim 13, further comprising:
a second beam current measuring device that measures a beam current of the ion beam directed in the irradiation-disabled direction,
wherein the processor determines that the beam deflection device is in the irradiation-disabled state and switches the beam blocking mechanism to the blocking state in a case where a beam current equal to or greater than a second predetermined value is measured with the second beam current measuring device.

17. An ion implantation method comprising:
(a) deflecting an ion beam by at least one of an electric field and a magnetic field in an irradiation-disabled direction in which a workpiece is incapable of being irradiated with the ion beam after a first workpiece is irradiated with the ion beam directed in an irradiation-enabled direction in which the workpiece is capable of being irradiated with the ion beam;
(b) moving the first workpiece from an ion implantation position, subsequently to the step (a);
(c) disposing a second workpiece different from the first workpiece at the ion implantation position, subsequently to the step (b); and
(d) returning the ion beam from the irradiation-disabled direction to the irradiation-enabled direction, subsequently to the step (c).

18. The ion implantation method according to claim 17,
wherein in the step (a), the ion beam is deflected in the irradiation-disabled direction by an electric field resulting from a voltage applied to a pair of electrodes facing each other with the ion beam interposed therebetween.

19. The ion implantation method according to claim 17,
wherein in the step (a), the ion beam is deflected in the irradiation-disabled direction by a magnetic field applied between a pair of magnetic poles facing each other with the ion beam interposed therebetween.

20. The ion implantation method according to claim 17,
wherein a deflection angle formed between the irradiation-enabled direction and the irradiation-disabled direction is from 2 degrees to 60 degrees.

21. The ion implantation method according to claim 20,
wherein the deflection angle formed between the irradiation-enabled direction and the irradiation-disabled direction is from 3 degrees to 45 degrees.

22. The ion implantation method according to claim 21,
wherein the deflection angle formed between the irradiation-enabled direction and the irradiation-disabled direction is from 5 degrees to 30 degrees.
